(19) United States
(12) Patent Application Publication
(10) Pub. No.: US 2006/0228828 A1
(43) Pub. Date: Oct. 12, 2006

(54) Versatile system for selective organic structure production

(76) Inventor: Seth Adrian Miller, Sachse, TX (US)

Correspondence Address: TEXAS INSTRUMENTS INCORPORATED, P O BOX 655474, M/S 3999, DALLAS, TX, 75265, US

(21) Appl. No.: 11/103,233

(22) Filed: Apr. 11, 2005

(51) Int. Cl. H01L 51/40

(52) U.S. Cl. 438/99

(57) ABSTRACT

The present invention provides a system for selectively forming an organic structure in a microelectromechanical device (100). According to the present invention, an encoder material is disposed along a surface (102) or substrate, to define a desired organic microstructure (104, 106). The encoder material may then be subjected to one or more intervening and possibly deleterious conditions, such as undercutting. Once such conditions are concluded, the encoder material is subjected to a stimulus that causes it to form the desired organic microstructure.

### TECHNICAL FIELD OF THE INVENTION

The present invention relates generally to the field of semiconductor device manufacturing and, more particularly, to apparatus and methods for selective placement or formation of structures comprising organic materials or compounds.

### BACKGROUND OF THE INVENTION

Semiconductor devices are ubiquitous in modern society, and this can largely be attributed to the success of wafer-scale semiconductor manufacturing processes. Semiconductor manufacturing infrastructure provides numerous prospects for the introduction and integration of new technologies within existing processes. Among recent developments, micro-electromechanical system (MEMS)—devices that have electrically controllable mechanical elements (such as actuators, gears, optical modulating elements, etc.)—have been formed monolithically on a semiconductor substrate using integrated circuit techniques. Further advances in the production of submicron scale electronic devices or systems (e.g., sensors) integrating, for example, biological materials (e.g., proteins), are currently being pursued with increasing levels of interest and exigency.

Introduction and integration of such new processes or materials within a standard manufacturing line is not trivial. Accommodating such new functionalities within the confines of existing manufacturing processes is often commercially unviable—if not impossible. In the case of MEMS, conventional silicon micromachining techniques often require anneal temperatures near 1000° C.—well in excess of what a standard CMOS semiconductor device can withstand. As a result, conventional MEMS devices are commonly built on their own manufacturing lines and, often, entirely separate from any associated semiconductor circuitry—despite a number of commonalities between them. These techniques thus require specialized materials and processes in order to produce a MEMS device—resulting in higher costs and a longer time to market for new MEMS products.

Similarly, the use of organic or biological material on a silicon platform has also generated new obstacles and concerns. Among such obstacles is the incompatibility of organic or biological material with many commercial semiconductor manufacturing processes. During manufacturing, semiconductor wafers, and the structures and materials deposited thereon, are exposed to a number of harsh or deleterious conditions—such as chemical solvents or high temperature environments. In many cases, exposure to such conditions can damage or destroy organic materials, degrading device performance or rendering a device useless. Conventional methods, therefore, often perform placement of organic-type material as a final fabrication step. This is generally the case where, for example, organic materials as provided as passivants in MEMS devices—the passivant is often applied in a final processing step.

This, unfortunately, is incongruous with the fact that, in a number of MEMS and other similar applications, the fabrication of very intricate, three-dimensional structures may require careful and precise placement or deposition of organic material at multiple points throughout a fabrication process. Thus, any attempts to mask off, build up, or build around the eventual location of a final-step organic-type structure are highly inefficient, and therefore not commercially viable.

As a result, there is a need for a system that provides selective formation of organic structures at various stages of a commercial semiconductor manufacturing processes, without significantly increasing production overhead or cost—one that is readily adaptable to address a wide variety of specific design requirements in an easy, efficient and cost-effective manner.

### SUMMARY OF THE INVENTION

The present invention provides a system for selective formation of organic structures within a semiconductor platform. The system of the present invention utilizes materials readily available within commercial semiconductor manufacturing processes, and enables efficient introduction of novel materials to such processes. The system of the present invention provides highly versatile and precise placement of one or more organic-type materials, throughout simple or complex structures. The system of the present invention is readily implemented without significantly increasing production overhead or cost. The system of the present invention thus addresses and overcomes a number of limitations associated with conventional approaches.

Specifically, the present invention provides a system that spatially directs or encodes one or more desired organic or biological materials to specific locations within or along a semiconductor structure. The present invention provides a system in which encoder materials or compounds are initially formed or placed where desired organic-type materials are needed or desired. The encoder materials are sufficiently robust to withstand necessary manufacturing processes and conditions—particularly deleterious ones (e.g., high temperature, plasma exposure). The eventual location of the desired organic-type materials may thus be encoded seamlessly at various points throughout a fabrication process, without requiring special construction processes.

When device manufacturing nears completion, a series of physical or chemical transformations may be employed to convert the encoder structures into structures having desired organic functionalities. In certain embodiments, for example, encoder materials may be sequentially coated with organic materials that react in a surface-specific manner. In other embodiments, an organic material may be reacted non-specifically with several encoders—and later converted to another chemical on an encoder surface by taking advantage of a specific reactivity of that encoder (e.g., sensitivity to UV light). The system of the present invention thus provides, by such structures and methods, a vehicle to exploit chemical or behavioral properties of various encoder or stimulus materials, in order to render desired surface characteristics (e.g., hydrophobic, hydrophilic) of a finished organic-type structure.

More specifically, according to the present invention, an organic structure is selectively formed along a microelectromechanical device, by disposing one or more encoder materials along a surface or substrate of the device. The encoder(s) is formed or placed to define a future location of a desired organic material or structure. Once the encoder material has been disposed, the device may then be subjected to one or more intervening and possibly deleterious conditions, such as undercutting, throughout the remainder of device fabrication. Once such conditions are over or completed, the encoder material is subjected to an appropriate stimulus (e.g., physical or chemical transformation) that causes it to form a desired organic film or structure displaying a desired performance or structural characteristic.

The present invention exploits the chemical or behavioral nature of inorganic materials—those referred to as encoders, and other inorganic materials within a device—to affect an organic transformation later in device processing in a desired manner. It should be understood, however, that according to the present invention, an inorganic material may have functionality that is complementary to, or independent from, its use as an encoder (e.g., reflective aluminum in a micromirror structure).

The present invention thereby provides a method of producing an organic surface or structure—having a desired location, orientation or property—upon a substrate. A first encoder material and a second encoder material are disposed along a substrate to define the desired organic surface or structure. The encoder materials may then be subjected to one or more intervening conditions throughout the remainder of fabrication and, once such conditions have passed, the encoder materials may be subjected to a stimulus that causes it to form the desired organic surface or structure.

The present invention further provides a method of producing a microelectromechanical structure on a semiconductor substrate. First and second encoder materials are disposed on the substrate to define first and second desired organic device structure, respectively. The first and second encoder materials are then subjected to one or more intervening conditions. After that, the first and second encoder materials are subjected to one or more stimuli, that cause one or both of the first and second encoder materials to react, forming one or both of the first and second desired organic device structures, respectively.

The present invention also provides a method of producing a device structure having a plurality of organic material surfaces or areas. A substrate is provided, upon which first and second encoder materials are disposed to define first and second desired organic areas along the device structure. The second encoder material is disposed on the substrate in close proximity or substantial contiguity to the first encoder material. The first and second encoder materials are subjected to one or more intervening conditions. Then, the first and second encoder materials are subjected to one or more stimuli that cause the first and second encoders to form the first and second desired organic areas, respectively.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration depicting one embodiment of a MEMS structure according to the present invention; and

FIG. 2 is an illustration depicting one embodiment of a MEMS structure in accordance with the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. For example, certain aspects of the present invention are described, for purposes of explanation and illustration, in conjunction with the placement of certain organic materials within a micro-electromechanical system (MEMS) device, using semiconductor manufacturing processes. Upon reference to the description of the present invention, however, it should be readily apparent that the principles and teachings of the present invention may be readily implemented with other device types, materials, or manufacturing systems where selective, precise, substitutional placement of an organic or biological material is required or desired. Therefore, the specific embodiments discussed herein are merely illustrative of specific ways to make and use the invention and do not limit the scope of the invention.

The system of the present invention provides selective formation of organic-type micron and submicron scale structures. According to the present invention, materials that are readily available within a commercial manufacturing process (e.g., semiconductor), as well as materials that may have been previously incompatible with such a process, are efficiently utilized to produce a desired structure. The system of the present invention provides highly versatile and precise placement of one or more organic or biological materials (hereafter, “organics”) in device structures of widely varying complexity. The formation of the organics within a device may occur while the device is in wafer form, as isolated chips, or in die form, while partially or completely packaged. The system of the present invention is readily implemented with only minimal processing overhead—providing significant design and performance advantages without significantly increasing production overhead or cost.

Certain aspects of the present invention are described, for purposes of explanation and illustration, hereinafter with reference to the production of a particular type of MEMS device—a micromirror device. As previously noted, MEMS are micron to sub-micron scale devices, often with moving parts. Micromirrors and other MEMS devices are typically fabricated on a semiconductor wafer using semiconductor techniques such as lithography, doping, metal sputtering, oxide deposition, and plasma etching—processes otherwise developed for and associated with the fabrication of integrated circuits. Micromirrors, such as the DMD™ micromirror array from Texas Instruments, are just one type of MEMS device. Other types of MEMS devices include accelerometers, pressure and flow sensors, gears and motors

Micromirror devices are primarily used in optical display systems. In a display system, a micromirror device functions as a light modulator that uses digital image data to modulate a beam of light by selectively reflecting portions of the beam of light to a display screen.

Micromirror devices have evolved rapidly over the past ten to fifteen years—changing from configurations that electrostatically deformed a flexible reflective surface to configurations that electrostatically move a support structure upon which a rigid reflective surface is disposed. Micromirror and other MEMS devices thus comprise a number of very fragile structures—making cost-effective manufacturing especially difficult.

For example, certain techniques for fabricating micromirror structures involve the selective deposition of one or more metal layers on top of one or more sacrificial layers. Such sacrificial layers often comprise a solvent/resin solution, such as photoresist. After the metal layers have been patterned and etched in a desired manner, then the sacrificial layers are removed—uncovering a freestanding micromirror structure. This is often referred to as undercutting the micromirror structure. Undercutting often involves the use of some cleansing solvent or some reactive process (e.g., plasma ash) to remove the sacrificial layer(s). Unfortunately, fragile micromirror structures, especially a passivation layer surface (e.g., a mirror surface), can be easily damaged by phenomena arising from such removal processes—such as loose particulate matter, excessive heat, or even capillary action of cleansing solvents.

Furthermore, once sacrificial layers beneath a micromirror structure have been removed, the mirrors and their support structures are highly susceptible to damage due to remaining or subsequently generated loose particulate matter. Because particles can become trapped in the delicate mechanical structure of a micromirror array and cannot be washed out, it is sometimes necessary to separate the devices from the wafers on which devices are formed, and wash any debris off the devices—prior to undercutting the micromirror structure(s). Moreover, because bond-out processes also create particles, it is often desirable or necessary to mount a device to a package substrate and perform chip bond-out prior to undercutting.

Unfortunately, it is only after the mirrors have been undercut that a micromirror array can be tested—as it is necessary to test physical performance characteristics, such as electrostatic movement of the array's constituent components. Thus, a micromirror device is often substantially fabricated and assembled before undercutting occurs. Depending upon the manufacturing processes involved, application of a passivation layer—which is designed to mitigate adhesion of moving components—may be have to be deposited or formed as part of a structure prior to undercutting. This delicate passivation layer is thereby necessarily to exposed to deleterious undercutting conditions, resulting in damage to the passivation layer and device yield loss.

This is especially true where thin film organics are used as or along a passivation layer. Thin film organics are useful in a number of MEMS applications—particularly the design, manufacture and operation of micromirror devices—where it is desirable if not necessary to maintain certain structural surfaces at specific energy levels. For example, a micromirror may be formed with a low-stiction, low-energy surface (e.g., hydrophobic)—so as to minimize the interproximal electrostatic, dispersive, and capillary forces between adjacent micromirror surfaces. A thin film organic, such as a self assembled monolayer (SAM) of a suitable organic (e.g. thiols on gold, silioxanes on silicon dioxide), is particularly beneficial in that it can provide such properties in a more efficient, high-performance manner than many available inorganic materials. A thin film organic may therefore be desirable for use as a passivation layer, in order to produce a surface (e.g., a reflective surface) having an optimal physical or functional property (e.g., hydrophobic).

Designers or manufacturers of micromirror and other MEMS devices—process-constrained by very complex device structural requirements—may thus be faced with a conundrum: choose to utilize organics to achieve a higher performance device, and accept increased yield loss and device malfunctions due to degradation or damage done to the organics during manufacture; or choose to avoid utilizing organics, thereby decreasing yield loss and device malfunction issues due to organic damage, but sacrifice efficiency and performance advantages resulting from organic implementations.

Comprehending these and other related issues, the present invention recognizes that selective chemistries and reactions may be exploited to overcome such barriers. The present invention provides a system that spatially directs or encodes the eventual location or position of one or more desired organic structures or surfaces within or along a device structure (e.g., a micromirror semiconductor device). Such organic features may comprise relatively simple surface areas, or may comprise more complex layered or three-dimensional structures. The present invention provides a system in which an encoder material or compound (hereafter, the “encoder”) is initially formed or placed where a desired organic is needed or desired. The encoder utilized is resistant or immune to degradation from various intervening treatments or conditions occurring throughout a manufacturing process, or provides a desirable reaction in a selective manner. The placement of the encoder may be performed at any suitable or desired stage of device manufacture, eliminating any need for complex fabrication schemes (e.g., multi-stage masking/etch). As the manufacturing process nears completion (i.e., deleterious conditions are concluded), the encoder may then be reacted or converted to a desired organic in one of a variety of ways.

In certain embodiments, an inorganic encoder is placed initially, and later reacted or passivated with a desired molecule in a surface-specific manner to form a desired organic structure on one encoder only. This reaction may be predicated primarily on the relative chemical reactivities of the encoders to drive the selectivity, or selectivity may be enhanced through the application of a stimulus, such as UV light, that enhances or limits the reactivity of one surface relative to another. The present invention thus utilizes preferential reactions between encoders and stimuli to render desired organic structures.

In other embodiments, a chemistry that is not surface-specific may be provided, such that many or all surfaces are reacted with an organic. This reaction is followed by exposure to a stimulus that selectively removes the organic from a specific encoder, in the presence of the others. Such a stimulus may comprise a surface-specific chemical reaction (e.g., with an acid or base), or some ambient physical stimulus (e.g., UV light, heat, etc.) that preferentially alters chemical reactivity of one surface vis-à-vis another. The present invention thus also provides a system by which the chemical or behavioral properties of various encoder materials may be manipulated or exploited in order to produce a finished structure or surface having desired physical or behavioral characteristics (e.g., hydrophobic, hydrophilic). By the present invention, the position of one or more organics can be encoded at various stages of a standard fabrication process, without actually exposing the organic(s) to harmful conditions occurring therein.

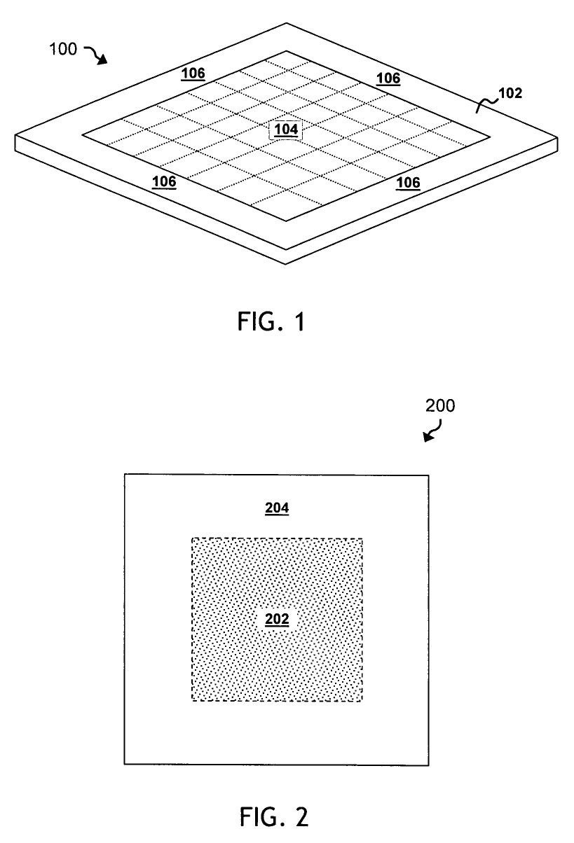

One such embodiment, and certain aspects of the present invention associated therewith, is described in greater detail with reference now to FIG. 1, which illustratively depicts a single micromirror device 100. Device 100 is depicted such that its upper surface 102 is shown. Upon completion of device 100, surface 102 should comprise an active area 104 and a bonding area 106. In the embodiment depicted, active area 104 comprises a micromirror array. Bonding area 106 comprises a bond line region around the outer perimeter of array 104, provided for necessary couplings to device 100 (e.g., packaging components, wire bond connections).

In device 100, the micromirror array of active area 104 comprises an upper layer material (e.g., aluminum, aluminum alloy) that, once passivated, will render a highly uniform, low-stiction organic surface. The exposed surface of bonding area 106 comprises an encoder compound such as titanium dioxide or titanium nitride. The encoder material is selected such that, in the absence of an appropriate stimulus (e.g., UV light), it reacts with a material eventually applied to passivate area 104. Both the upper layer material of area 104 and the encoder material of area 106 may thus be formed or disposed prior to undercutting. Undercutting does not have a deleterious effect on the stiction characteristics of area 104, since that area's passivated organic has not yet been formed. Once undercutting is complete, an appropriate passivating material (e.g., alkyl-based carboxylic acid) may then be uniformly applied across surface 102—passivating area 104 and rendering it with its desired functional characteristics. The passivating material may be applied without any special masking of area 106, since the information necessary to control the eventual surface characteristics of the area is encoded in the surface material itself.

Once area 104 is sufficiently passivated, surface 102 is exposed to a stimulus that initiates a reaction (e.g., oxidation), between the encoder material and the passivating material disposed thereon, that destroys the passivation layer atop only area 106—leaving behind a suitable high-energy surface for bonding or coupling needs. In the embodiment depicted in FIG. 1, the encoder material is a photoactive compound (e.g., titanium dioxide, titanium nitride, titanium oxynitride)—reactive to the passivating material in UV light, especially in the presence of oxygen. Depending upon the particular embodiment, the selective reaction may reduce the organic atop area 106 completely, or substantially. The active area material, encoder material, and passivating material are thus selected such that the desired reaction selectively occurs only where the encoder material resides. Once the selective reduction has been completed, that encoder may be selectively reacted with another organic that might, for example, improve adhesion of the bond area with an epoxy.

Alternative embodiments may utilize other encoder materials responsive to other stimulus (e.g., temperature, chemical exposure), as long as such stimulus does not detrimentally affect the passivated organic in the active area. For example, native oxides of both aluminum and silicon may be reacted, in a non-selective manner, with an alkyl siloxane in solution or gas phase. The alkyl siloxane may be selectively removed from an aluminum surface by taking advantage of its lower thermal and hydrolytic stability on aluminum. For example, triskadecafluorooctyltrichlorosilane forms a monolayer on silicon dioxide surfaces that is stable to above 400° C. Such a monolayer on aluminum will decompose at temperatures above 300° C. Thus, by heating to some intermediate temperature, such a monolayer may be selectively removed from an aluminum surface. Similarly, steam or an aqueous acid or base may be used to selectively remove a monolayer from an aluminum surface in the presence of a silicon surface. If desired, once an original organic is stripped, aluminum may be further reacted with a second organic (for instance, an alkyl carboxylic acid). In such a manner, a designer or manufacturer may encode an eventual location for a device feature, early in a fabrication process, without impeding intricate processes necessary to form a device or structure.

In other embodiments of the present invention, certain organics having differing physical or behavioral characteristics may be formed or disposed along a substrate in proximity to one another using the encoding scheme described herein. These organics may be contiguous and co-planar, laterally contiguous, partially contiguous, or even spatially is separated by some nominal distance. It should be understood that all such variations, and varying combinations thereof, may be easily produced with the present invention. Such embodiments are described in greater detail beginning with reference to FIG. 2, which illustratively depicts a single micromirror structure 200, from a top surface view. Structure 200 is designed such an inner area 202, of certain physical properties or functional characteristics, is surrounded by an outer area 204, of differing physical properties or functional characteristics. This embodiment may be utilized, for example, where areas of differing hydrophobicity, along a single device surface, are desired. For example, in certain embodiments, area 202 may comprise a hydrophobic surface while area 204 comprises a hydrophilic surface. In other embodiments, area 202 may comprise a surface that is electrochemically active (e.g., oxidizable or reducible), while area 204 comprises a surface that is relatively more inert. Other similar variations and combinations are thus comprehended by the present invention.

In structure 200, therefore, it may be necessary to form area 202 and area 204 as adjoining but non-homogenous organic surfaces. Again, encoders are utilized to prevent damage to the organics during fabrication. Inorganic encoders in areas 202 and 204 may be passivated, after undercutting or other deleterious processing, to form desired organics. Selective chemistries may be utilized such that a first passivating material, reactive only with area 202, is applied, followed by the application of a second passivating material, reactive only with area 204. In other embodiments, the order in which areas 202 and 204 are passivated may be reversed, or temporally separated by some required or desired amount of time (e.g., for drying or cleaning). Other similar variations and combinations are thus comprehended by the present invention.

For purposes of explanation and illustration, however, structure 200 has an inner region 202 that, upon completion, comprises a highly reflective and hydrophobic organic surface (e.g., on an aluminum compound), while outer region 204 comprises a hydrophilic organic surface (e.g., on an SiOₓ compound). An appropriate material is provided for passivating the surface of region 202—one that passivates region 202 without reaction at region 204. For example, the surface of an aluminum-based encoder reacts, at general ambient conditions (e.g., room temperature and pressure), with solutions of carboxylic or phosphonic acids, whereas a silica-based surface does not. Thus, an aluminum-based encoder may be selectively reacted with, for example, an organic phosphonate to produce a desired physical or functional characteristic (e.g., hydrophobicity) along the surface of region 202. Further treatment or passivation of structure 200 under such conditions may comprise exposing the surface of regions 202 and 204 to a chemistry (an alkene, at elevated temperature, or an organosilane reagent) that reacts only with the surface of a silica-based region 204, to produce a desired organic surface. This second passivation is provided without causing an interaction with the already passivated surface of region 202—and may therefore be utilized to produce a desired physical or functional property (e.g., hydrophilicity), disparate from the surface properties of region 202, along the surface of region 204.

Thus, utilizing the present invention, a plurality of non-homogenous organic surfaces may be produced at desired locations, in desired configurations, along the surface of a micromirror or other MEMS structure. The placement of the initial encoders may be provided in a wide variety of manners—providing a great deal of design flexibility and ready adaptability to a number of commercially viable fabrication processes. For example, the encoders may be formed or placed on the surface of structure 200 by layering them in a stack, and then selectively removing one material by conventional lithography followed by etch. In other embodiments, a thin film of one encoder material may be placed or formed atop another encoder material, and patterned by a lift-off or etch process, for example. In these and other embodiments, the materials may be formed or placed by any suitable deposition or growth process (e.g., sputtering, vapor deposition). Furthermore, the placement or formation of the encoders can be integrated at any desired or required point in the fabrication process—sequentially, concurrently, or independently. The present invention thus provides the ability to easily and reliably form complex microstructures in-process, without requiring substantial process modifications.

Thus, by the present invention, the eventual position of one or more organic surfaces may be defined or encoded by the initial placement or formation of a encoder material—one that can withstand intervening process or handling conditions (e.g., undercutting) that would otherwise damage or destroy its corresponding organic. The present invention thereby enables the production of microstructures and surfaces comprising multiple, contiguous or non-contiguous, non-homogenous organic materials (e.g., a SAM). By the present invention, the desired organics may be easily formed at a desired, later stage of fabrication by reacting the organic's encoder with an appropriate stimulus. That stimulus may comprise subjecting an encoder to one or more chemical or physical stimuli, independently or in combination. According to the present invention, therefore, the placement or configuration of the organic structure can take place at an intermediate step of fabrication of the device or structure, rather than as the final step.

As previously discussed, the embodiments and examples set forth herein are therefore presented to best explain the present invention and its practical application, and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. A number of embodiments and variations of micromirror and other MEMS structures are comprehended by the present invention. For example, the present invention may be utilized to form adjoining areas of biological or organic material using fabrication processes other than the commercial semiconductor processes referenced above—such as utilizing bio-compatible and antigen encoders to effect a desired protein configuration. Thus, as indicated, a number of modifications and variations are possible in light of the above teaching without departing from the spirit and scope of the following claims.

What is claimed is:

1. A method of producing an organic device structure upon a substrate, the method comprising the steps of:
providing a substrate;
providing a first encoder material;
providing a second encoder material;
disposing the first and second encoder materials on the substrate to define a desired organic device structure;
subjecting the first and second encoder materials to one or more intervening conditions; and
subjecting the first and second encoder materials to one or more stimuli that cause one or both of the first and second encoder materials to react, forming the desired organic device structure.

2. The method of claim 1, wherein the step of providing a substrate further comprises providing a semiconductor substrate.

3. The method of claim 1, wherein either of the steps of providing first or second encoder materials further comprises providing an inorganic material from a commercial semiconductor fabrication process.

4. The method of claim 3, wherein the inorganic material is selected from a group comprising: a metal oxide, a semiconductor oxide, a metal nitride, a semiconductor nitride, a noble metal, and a metal predisposed to forming surface oxidation.

5. The method of claim 1, wherein the step of subjecting the first and second encoder materials to one or more intervening conditions further comprises subjecting the first and second encoder materials to heat.

6. The method of claim 5, wherein the step of subjecting the first and second encoder materials to one or more intervening conditions further comprises subjecting the first and second encoder materials to heat above 200° C.

7. The method of claim 1, wherein the step of disposing the first and second encoder materials on the substrate to define a desired organic device structure further comprises disposing either the first or the second encoder material on the substrate to define a desired hydrophobic surface.

8. The method of claim 1, wherein the step of disposing the first and second encoder materials on the substrate to define a desired organic device structure further comprises disposing either the first or the second encoder material on the substrate to define a desired hydrophilic surface.

9. The method of claim 1, wherein the step of subjecting the first and second encoder materials to one or more intervening conditions further comprises subjecting the first and second encoder materials to one or more chemical reagents.

10. The method of claim 1, wherein the step of subjecting the first and second encoder materials to one or more stimuli that cause one or both of the first and second encoder materials to react further comprises subjecting the first and second encoder materials to one or more organic materials.

11. The method of claim 10, wherein the step of subjecting the first and second encoder materials to one or more stimuli further comprises exposing the first and second encoder materials to one or more organic materials selected from a group consisting of: alkenes, carboxylic acids, phosphonic acids, siloxanes, amines, alcohols, thiols, carbamates, imines, and isothiocyanates.

12. The method of claim 10, wherein the step of subjecting the first and second encoder materials to one or more stimuli further comprises subjecting the first and second encoder materials to a secondary stimulus after the first and second encoder materials are subjected to one or more organic materials.

13. The method of claim 12, wherein the step of subjecting the first and second encoder materials to a secondary stimulus further comprises subjecting the first and second encoder materials to ultraviolet light after the first and second encoder materials are subjected to one or more organic materials.

14. The method of claim 12, wherein the step of subjecting the first and second encoder materials to one or more organic materials to a secondary stimulus further comprises subjecting the first and second encoder materials to a chemical reactant after the first and second encoder materials are subjected to one or more organic materials.

15. The method of claim 12, wherein the step of subjecting the first and second encoder materials to a secondary stimulus reduces organic material from either the first or second encoder material.

16. The method of claim 10, wherein the step of subjecting the first and second encoder materials to one or more stimuli that cause one or both of the first and second encoder materials to react further comprises subjecting the first and second encoder materials to a first organic material and a second organic material, wherein the first organic material reacts preferentially with the first encoder material, and the second organic material reacts preferentially with the second encoder material.

17. The method of claim 1, wherein the step of disposing the first and second encoder materials on the substrate to define a desired organic device structure further comprises disposing the first and second encoder materials substantially contiguous on the substrate.

18. A method of producing a microelectromechanical structure, the method comprising the steps of:
providing a semiconductor substrate;
providing a first encoder material;
providing a second encoder material;
disposing the first encoder material on the substrate to define a first desired organic device structure;
disposing the second encoder material on the substrate to define a second desired organic device structure;
subjecting the first and second encoder materials to one or more intervening conditions; and
subjecting the first and second encoder materials to one or more stimuli that cause one or both of the first and second encoder materials to react, forming one or both of the first and second desired organic device structures, respectively.

19. The method of claim 18, wherein either the step of providing a first encoder material or the step of providing a second encoder material further comprises providing a photo-reactive encoder material.

20. The method of claim 18, wherein the step of disposing the first encoder material to define a first desired organic device structure further comprises disposing a first encoder material to define a hydrophilic surface.

21. The method of claim 18, wherein the step of disposing the first encoder material to define a first desired organic device structure further comprises disposing a first encoder material to define a hydrophobic surface.

22. The method of claim 18, wherein the microelectromechanical structure produced is a micromirror device.

23. A method of producing a device structure having a plurality of organic material areas, the method comprising the steps of:
providing a substrate;
providing a first encoder material;
providing a second encoder material;
disposing the first encoder material on the substrate to define a first desired organic area along the device structure;
disposing the second encoder material on the substrate, proximal to the first encoder material, to define a second desired organic area along the device structure;
subjecting the first and second encoder materials to one or more intervening conditions; and
subjecting the first and second encoder materials to one or more stimuli that cause the first and second encoders to form the first and second desired organic areas, respectively.

24. The method of claim 23, wherein the device structure produced is a microelectromechanical structure.

25. The method of claim 23, wherein the device structure produced is a micromirror structure.

26. The method of claim 23, wherein the step of subjecting the first and second encoder materials to one or more intervening conditions further comprises subjecting the first and second encoder materials to undercutting.

27. The method of claim 22, wherein the step of subjecting the first and second encoder materials to one or more stimuli further comprises subjecting the first and second encoder materials to an organic material that reacts preferentially with either the first encoder material or the second encoder material.

28. The method of claim 22, wherein the step of subjecting the first and second encoder materials to one or more stimuli further comprises subjecting the first and second encoder materials to an organic material that reacts with both the first and second encoder materials.

29. The method of claim 22, wherein the step of disposing the second encoder material on the substrate, proximal to the first encoder material, further comprises disposing the second encoder material on the substrate substantially contiguous to the first encoder material.

30. The method of claim 22, wherein the step of disposing the second encoder material on the substrate, proximal to the first encoder material, further comprises disposing the second encoder material on the substrate contiguous to the first encoder material.
